(19) United States
(12) Patent Application Publication
(10) Pub. No.: US 2025/0357248 A1
(43) Pub. Date: Nov. 20, 2025

(54) DEVICE COMPRISING THERMALLY ANISOTROPIC CONDUCTIVE CHANNELS AND THERMALLY INSULATING MATERIAL

(71) Applicant: QUALCOMM Incorporated, San Diego, CA (US)

(72) Inventors: Peng WANG, San Diego, CA (US); Bohan YAN, San Diego, CA (US); Hui HE, Changsha (CN)

(21) Appl. No.: 18/870,923

(22) PCT Filed: Jun. 29, 2022
(86) PCT No.: PCT/CN2022/102293

§ 371 Date: Dec. 2, 2024

(51) Int. Cl. H01L 23/373; H05K 7/20

(52) U.S. Cl. CPC H01L 23/373; H05K 7/2039

(57) ABSTRACT

A device comprising a region that includes a component configured to generate heat and a thermally conductive layer coupled to the region, where the thermally conductive layer includes a plurality of segmented thermally anisotropic conductive channels. Each segmented thermally anisotropic conductive channel from the plurality of segmented thermally anisotropic conductive channels is aligned in a first direction. Each segmented thermally anisotropic conductive channel from the plurality of segmented thermally anisotropic conductive channels is configured to provide heat transfer capabilities in the first direction. The thermally conductive layer is configured to (i) reduce the junction temperature of the component and/or (ii) reduce a surface temperature of the device.

### FIELD

Various features relate to a device that includes a heat dissipating component.

### BACKGROUND

Electronic devices include many components that generate heat, such as integrated devices. Integrated devices may be prone to overheating, which can affect the performance of the integrated devices and other components of the electronic device. An integrated device that is overheating has a high junction temperature, which can result in high surface temperature for the electronic device. This may ultimately affect the performance of the electronic device. There is an ongoing need to improve the heat dissipating performance of an electronic device that includes a component that generates heat. For example, there is an ongoing need to reduce the junction temperature of components that generate heat and/or reduce the surface temperature of an electronic device that includes components that generate heat.

### SUMMARY

Various features relate to a device that includes a heat dissipating device.

One example provides a device comprising a region that includes a component configured to generate heat and a thermally conductive layer coupled to the region, where the thermally conductive layer includes a plurality of segmented thermally anisotropic conductive channels.

Another example provides a device comprising a region that includes a first integrated device configured to generate heat and a second integrated device configured to generate heat. The device comprises means for segmented anisotropic heat transfer coupled to the region.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary front side view of an electronic device that includes a display.

FIG. 2 illustrates an exemplary back side view of an electronic device that includes two integrated devices.

FIG. 3 illustrates a cross sectional profile view of a device that includes a thermally conductive layer comprising thermally conductive channels.

FIG. 4 illustrates an exemplary view of a sheet that is thermally anisotropic along a plane.

FIG. 5 illustrates an exemplary view of a thermally conductive layer comprising thermally conductive channels.

FIG. 6 illustrates an exemplary plan view of a thermally conductive layer comprising thermally conductive channels.

FIG. 7 illustrates an exemplary plan view of a thermally conductive layer comprising thermally conductive channels and a thermally insulating material.

FIG. 8 illustrates an exemplary plan view of a thermally conductive layer comprising thermally conductive channels and several thermally insulating materials.

FIG. 9 illustrates an exemplary plan view of a thermally conductive layer comprising thermally conductive channels aligned in different directions.

FIG. 10 illustrates an exemplary plan view of a thermally conductive layer comprising thermally conductive channels aligned in different directions.

FIG. 11 illustrates an exemplary plan view of a thermally conductive layer comprising thermally conductive channels aligned in different directions.

FIG. 12 illustrates an exemplary plan view of a thermally conductive layer comprising thermally conductive channels aligned in different directions.

FIG. 13 illustrates an exemplary junction temperature map for a device without the use of a thermally conductive layer comprising thermally conductive channels.

FIG. 14 illustrates an exemplary junction temperature map for a device with the use of a thermally conductive layer comprising thermally conductive channels.

FIG. 15 illustrates an exemplary surface temperature map for a device without the use of a thermally conductive layer comprising thermally conductive channels.

FIG. 16 illustrates an exemplary surface temperature map for a device with the use of a thermally conductive layer comprising thermally conductive channels.

FIG. 17 illustrates an exemplary sequence for fabricating a thermally conductive layer comprising thermally conductive channels.

FIG. 18 illustrates an exemplary sequence for fabricating a thermally conductive layer comprising thermally insulating portions and thermally conductive channels aligned in different directions.

FIG. 19 illustrates an exemplary flow diagram of a method for providing a thermally conductive layer comprising thermally insulating portions and thermally conductive channels aligned in different directions.

FIG. 20 illustrates various electronic devices that may integrate a die, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device (e.g., electronic device) comprising a region that includes a component configured to generate heat and a thermally conductive layer coupled to the region, where the thermally conductive layer includes a plurality of segmented thermally anisotropic conductive channels. Each segmented thermally anisotropic conductive channel from the plurality of segmented thermally anisotropic conductive channels is aligned in a first direction. Each segmented thermally anisotropic conductive channel from the plurality of segmented thermally anisotropic conductive channels has a high thermal conductivity in the first direction and a low thermal conductivity in another direction. For example, each segmented thermally anisotropic conductive channel from the plurality of segmented thermally anisotropic conductive channels is configured to provide heat transfer first (e.g., initially) primarily in the first direction. The thermally conductive layer may include graphite (e.g., graphite sheet). The thermally conductive layer is configured to provide localized directional heat transfer to enable thermal decoupling between components in the device. For example, as will be further described below, the region may include a first integrated device and a second integrated device, and the thermally conductive layer may be configured to provide heat transfer and/or dissipate heat in such a way that heat generated by one integrated device does not dissipate (or minimally dissipates) towards the other integrated device. As will be further described below, the use of a plurality of thermally anisotropic conductive channels helps reduce the integrated device junction temperatures and device surface temperatures.

### Exemplary Device Comprising a Layer Having Thermally Conductive Channels

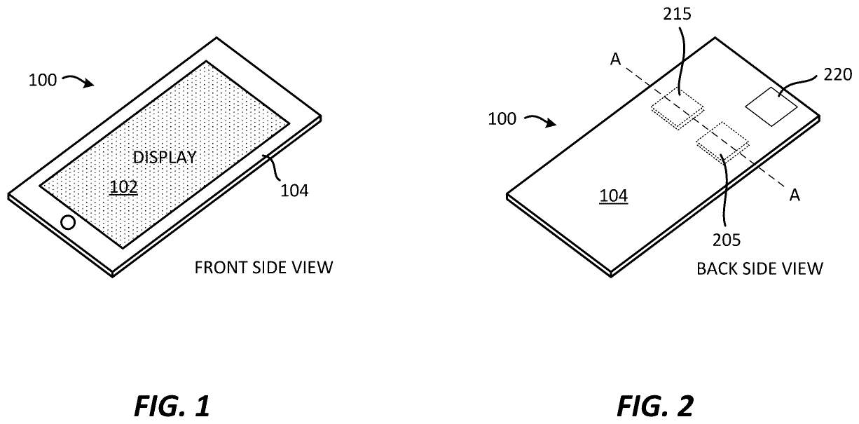

FIGS. 1 and 2 illustrate a device 100 that may include at least one thermally conductive layer comprising thermally conductive channels. The device 100 may include an electronic device, such as mobile phone (e.g., smart phone). FIG. 1 illustrates an exemplary front side view of a device 100 that includes a display 102 and a casing body 104. FIG. 2 illustrates an exemplary back side view of the device 100. The device 100 includes an integrated device 205, an integrated device 215 and a camera 220. The integrated device 205 may be a first integrated device. The integrated device 215 may be a second integrated device. The integrated device 205 and the integrated device 215 are located inside the device 100. For example, the integrated device 205 and the integrated device 215 are located inside the casing body 104. The camera 220 may be at least partially embedded in the casing body 104 of the device 100.

As will be further described below, the device 100 may include at least one thermally conductive layer comprising thermally conductive channels. The thermally conductive channels may be thermally anisotropic conductive channels that are configured to (i) provide high thermal conductivity along a first direction (e.g., length), and (ii) low thermal conductivity along another direction (e.g., width). For example, the thermally conductive channels may be thermally anisotropic conductive channels that are configured to (i) initially provide heat transfer primarily (e.g., substantially, mostly, almost entirely) along a length of the thermally conductive channels and (ii) initially provide little or no heat transfer along other directions (e.g., second direction, third direction, width). This configuration may help ensure that heat generated by the integrated device 205 does not initially dissipate towards the integrated device 215 and/or heat generated by the integrated device 215 does not dissipate towards the integrated device 205. Thus, the layer (e.g., thermally conductive layer, heat transfer layer) may be configured to provide localized directional heat transfer to enable thermal decoupling between components (e.g., integrated devices) in the device 100, while still providing effective and efficient heat dissipation from one or more components configured to generate heat.

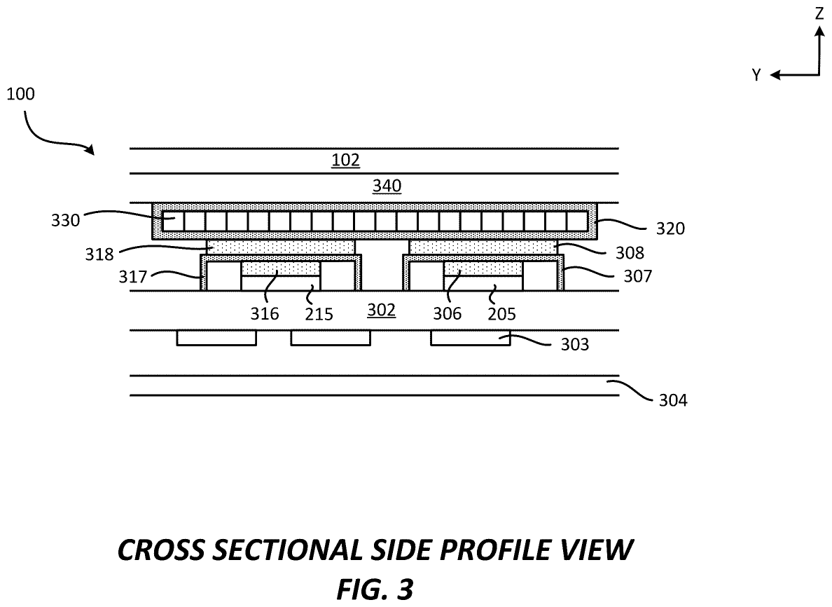

FIG. 3 illustrates an exemplary cross sectional profile view of the cross section AA of the device 100 of FIG. 2. The device 100 includes the display 102, a back cover 304, a board 302, a plurality of components 303, the integrated device 205, the integrated device 215, a thermal interface material 306, a thermal interface material 316, a shield 307, a shield 317, a thermal interface material 308, a thermal interface material 318, a heat transfer component 320, a thermally conductive layer 330, and a display module 340. The back cover 304 may be part of the casing body 104 of the device 100.

The thermally conductive layer 330 includes thermally anisotropic conductive channels that are configured to (i) provide high thermal conductivity along a first direction (e.g., length), and (ii) low thermal conductivity along another direction (e.g., width, second direction). Examples of thermally conductive layers are further described below in at least FIGS. 5-12.

The board 302 may be a printed circuit board (PCB). The plurality of components 303 may be coupled to a back surface of the board 302. The plurality of components 303 may face the back cover 304 of the device 100. The integrated device 205 and/or the integrated device 215 may be coupled to the front side of the board 302, through a plurality of solder interconnects (not shown). The thermal interface material 306 may be coupled to a back side of the integrated device 205. The shield 307 may be coupled to the board 302 and may surround the integrated device 205. The shield 307 may be coupled to the integrated device 205 through the thermal interface material 306. The thermal interface material 316 may be coupled to the back side of the integrated device 215. The shield 317 may be coupled to the board 302 and may surround the integrated device 215. The shield 317 may be coupled to the integrated device 215 through the thermal interface material 316. The shield 307 and/or the shield 317 may include electrically conductive material (e.g., metal, copper) and may be configured to operate as an electromagnetic interference (EMI) shield. The shield 307 and/or the shield 317 may be configured to be coupled to ground.

The thermal interface material 308 is coupled to the shield 307. The thermal interface material 318 is coupled to the shield 317. The thermal interface material 308 and the thermal interface material 318 are coupled to the heat transfer component 320. The thermally conductive layer 330 may be located inside the heat transfer component 320. The thermally conductive layer 330 may include one or more thermally conductive layers. In some implementations, the thermally conductive layer 330 may be partially covered by the heat transfer component 320. For example, one side of the thermally conductive layer 330 is coupled to the heat transfer component 320, and another side of the thermally conductive layer 330 is directly coupled to the thermal interface material 308 and/or the thermal interface material 318. The heat transfer component 320 may have different shapes and/or sizes. For example, the heat transfer component 320 may be configured to be a case and/or a plate for the thermally conductive layer 330. The heat transfer component 320 is coupled to the display module 340. The display module 340 may or may not be in contact with the display 102. The heat transfer component 320 may help with the handling and placement of the thermally conductive layer 330 in a device. In some implementations, the heat transfer component 320 may be optional. In such instances, the thermally conductive layer 330 may be directly coupled (e.g., directly touching) to the display module 340, the thermal interface material 308 and/or the thermal interface material 318.

FIG. 3 illustrates an example of a device 100 that includes a region that includes at least one component that is configured to generate heat, where a thermally conductive layer is coupled (e.g., directly or indirectly) to the region that includes at least one component that is configured to generate heat. The region of the device 100 that includes a component that is configured to generate heat, may include the integrated device 205 (e.g., first integrated device) and/or the integrated device 215 (e.g., second integrated device). Thus, the integrated device 205 and/or the integrated device 215 are examples of components that may be configured to generate heat. In some implementations, the thermally conductive layer 330 may be considered to be in the region that includes at least one component that is configured to generate heat. Different implementations may define a region of a device 100 differently. The region of a device 100 may include an internal region of the device 100. A thermally conductive layer (e.g., 330) that is coupled to a region of the device 100 may mean that the thermally conductive layer is coupled (e.g., directly coupled, indirectly coupled, mechanically coupled) to one or more components and/or one or more parts in the region of the device 100. As will be further in described in detail below, the thermally conductive layer 330 may be configured to provide localized directional heat transfer to enable thermal decoupling between the integrated device 205 and the integrated device 215 (and possibly other components) through the use of thermally anisotropic conductive channels. The thermally conductive layer 330 may have different shapes, sizes, configurations and/or arrangements. In one example, the thermally conductive layer 330 may have a thickness of about 0.8 millimeters. In one example, the heat transfer component 320 may have a total thickness of about 1 millimeters. However, the heat transfer component 320 may have other thicknesses. FIGS. 5-12 below illustrate and describe different examples of configurations of thermally conductive layers that may be implemented as the thermally conductive layer 330 and/or with the thermally conductive layer 330 in the device 100. The thermally conductive layer 330 may be a means for segmented anisotropic heat transfer.

It is noted that the configuration and/or arrangement shown in FIG. 3 is exemplary. In some implementations, other components may be present, some of the components may be located differently in the device 100, and/or some of the components may be optional.

It is noted that in the disclosure, numerous coordinate systems (X-Y-Z, X′-Y′-Z′, X″-Y″-Z″) are used and described. These exemplary coordinate systems are used to help explain the anisotropic thermal properties of the thermally conductive layer and/or the segmented thermally conductive channels. These different coordinate systems may be independent of each other or they may be related to one or more coordinate systems. Other coordinate systems may be used to illustrate orientations and/or alignment.

An integrated device (e.g., 205, 215) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 205, 215) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using one or more fabrication processes that provide better yield compared to a fabrication process used on another type of integrated device, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

One or more of the integrated devices may be implemented in a radio frequency (RF) package. The RF package may be a radio frequency front end (RFFE) package. A package may be configured to provide Wireless Fidelity (WiFi) communication and/or cellular communication (e.g., 2G, 3G, 4G, 5G). The packages may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

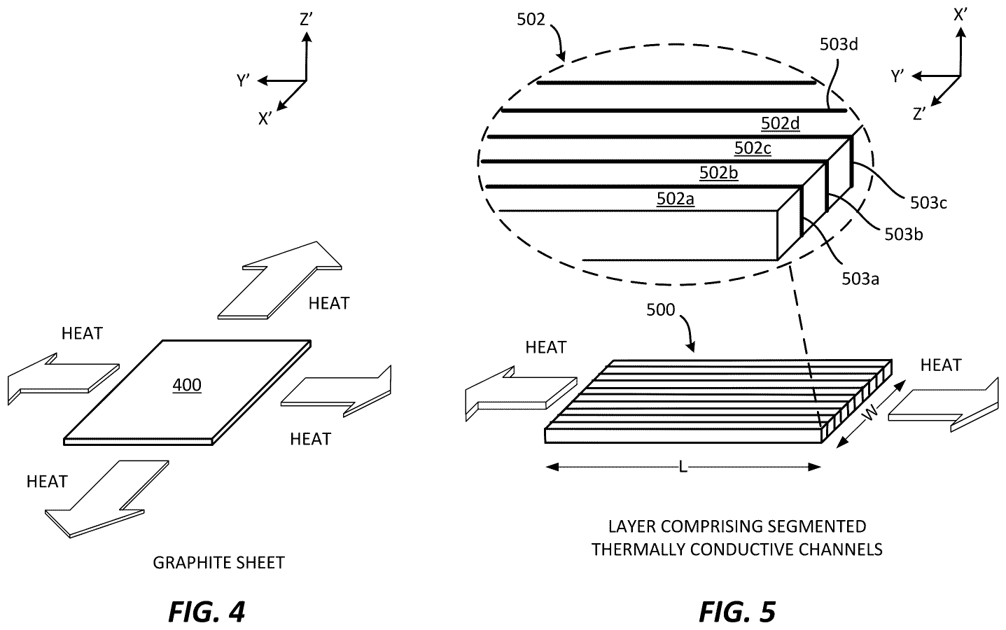

FIG. 4 illustrates an exemplary view of a thermally conductive sheet 400. The thermally conductive sheet 400 may be thermally anisotropic conductive along a plane. The thermally conductive sheet 400 is configured to provide high heat transfer capabilities (e.g., dissipate heat) primarily along a plane (e.g., X′-Y′ plane). Thus, heat can dissipate well along any direction of the plane (e.g., X′-Y′). However, the thermally conductive sheet 400 provides poor, little (in relative terms compared to heat transfer along the plane) or no heat transfer capabilities in other directions and/or other planes. For example, the thermally conductive sheet 400 provides little or no heat transfer capabilities in the Z′ direction, the Z′ direction of the X′-Z′ plane and/or the Z′ direction of the Y′-Z′ plane. The thermally conductive sheet 400 may include graphite (e.g., graphite sheet). In some implementations, the thermally conductive sheet 400 in the X′-Y′ plane, has a thermal conductivity in a range of approximately 1000-1900 Watts per meter kelvin (W/(mk)). Thus, along any direction of the plane (e.g., X′-Y′), the thermally conductive sheet 400 has a thermal conductivity in a range of approximately 1000-1900 Watts per meter kelvin (W/(mk)). In some implementations, the thermally conductive sheet 400 in the Z′ direction has a thermal conductivity that is less than 30 Watts per meter kelvin (W/(mk)) (e.g., 3.5 W/(mk)).

FIG. 5 illustrates an exemplary view of a thermally conductive layer 500. The thermally conductive layer 500 may be thermally anisotropic conductive along a direction on a plane. The thermally conductive layer 500 includes a plurality of segmented thermally conductive channels 502 (e.g., segmented thermally anisotropic conductive channels). The thermally conductive layer 500 is configured to provide heat transfer (e.g., dissipate heat) primarily along a direction (e.g., Y′ direction) in a plane (e.g., Y′-Z′ plane). Thus, heat can dissipate well along the Y′ direction of the plane (e.g., Y′-Z′). However, the thermally conductive sheet 400 may provide little (relative to the direction that is capable to provide the most heat transfer) or no heat transfer capabilities in other directions and/or other planes. For example, the thermally conductive layer 500 may provide little or no heat transfer capabilities in the Z′ direction (e.g., little or no heat transfer between segmented thermally conductive channels 502). The thermally conductive layer 500 may include graphite (e.g., graphite sheet). In some implementations, the thermally conductive layer 500 in the Y′ direction of the Y′-Z′ plane, has a thermal conductivity in a range of approximately 1000-1900 Watts per meter kelvin (W/(mk)). In some implementations, the thermally conductive layer 500 in the Z′ direction has a thermal conductivity that is less than 30 Watts per meter kelvin (W/(mk)) (e.g., 3.5 W/(mk)). The segmented thermally conductive channel (e.g., 502) may include a thermally conductive material that has a high thermal conductivity value in the first direction, but has a low thermal conductivity value in at least a second direction. For example, at least one segmented thermally conductive channel includes a thermally conductive material that has a high thermal conductivity value along the length of the segmented thermally conducive channel, but has a low thermal conductivity value towards a neighboring segmented thermally conductive channel. The segmented thermally conductive channel includes a thermally conductive material that has a relatively high thermal conductivity value in the first direction, but has a relatively low thermal conductivity value in at least a second direction. The segmented thermally conductive channel has a relatively high thermal conductivity value in the first direction (e.g., along length of a channel), but has a relatively low thermal conductivity value in at least a second direction (e.g., along a width of one or more channel(s)). Thus, the thermally conductive layer 500 includes segmented thermally anisotropic conductive channels (e.g., 502) that are configured to (i) provide high thermal conductivity along a first direction (e.g., length), and (ii) low thermal conductivity along another direction (e.g., width, second direction).

The term “high thermal conductivity value” may be high in absolute terms and/or in relative terms to another thermal conductivity value. The term “low thermal conductivity value” may be low in absolute terms and/or in relative terms to another thermal conductivity value. The term “relatively high thermal conductivity value”, as used in the disclosure may mean a thermal conductivity value that is at least 5 times higher than that of a “relatively low thermal conductivity value”. For example, a relatively high thermal conductivity value may have a thermal conductivity value that is at least 5 times higher than that of a relatively low thermal conductivity value. In another example, a relatively high thermal conductivity value may have a thermal conductivity value that is at least 10 times higher than that of a relatively low thermal conductivity value. In yet another example, a relatively high thermal conductivity value may have a thermal conductivity value that is at least 100 times higher than that of a relatively low thermal conductivity value. Thus, a first directional thermal conductivity value (e.g., high thermal conductivity value) may have a thermal conductivity value that is at least 5 times higher (e.g., at least 10 times higher, at least 100 times higher) than that of a second directional thermal conductivity value (e.g., relatively low thermal conductivity value). It is noted that the range of thermal conductivity values mentioned and described in the disclosure are exemplary. Different materials may have different thermal conductivity values, such as higher and/or lower values than the thermal conductivity values mentioned and described in the disclosure.

The plurality of segmented thermally conductive channels 502 includes a first segmented thermally conductive channel 502a, a second segmented thermally conductive channel 502b, a third segmented thermally conductive channel 502c and a fourth segmented thermally conductive channel 502d.

As shown in FIG. 5, each segmented thermally conductive channel from the plurality of segmented thermally conductive channels 502 is aligned in a first direction (e.g., Y′ direction) along a plane (e.g., Y′-Z′ plane). For example, a length of each segmented thermally conductive channel from the plurality of segmented thermally conductive channels 502 is aligned in the first direction (e.g., Y′ direction) along a plane (e.g., Y′-Z′ plane). Moreover, each segmented thermally conductive channel (e.g., 502a, 502b, 502c, 502d) from the plurality of segmented thermally conductive channels 502 includes a thermally anisotropic conductive channel that is configured to provide heat transfer primarily in the first direction (e.g., Y′ direction, along the length of the segmented thermally conductive channel) of a first plane (e.g., Y′-Z′ plane). The plurality of segmented thermally conductive channels 502 are bonded through at least one adhesive 503. The at least one adhesive 503 may include glue and/or a bonding agent. The at least one adhesive 503 may include an adhesive 503a, an adhesive 503b, an adhesive 503c, and an adhesive 503d. The at least one adhesive 503 may be located between segmented thermally conductive channels (e.g., 502a, 502b, 502c, 502d). For example, an adhesive 503a may be located between the first segmented thermally conductive channel 502a and the second segmented thermally conductive channel 502b. An adhesive 503b may be located between the second segmented thermally conductive channel 502b and the third segmented thermally conductive channel 502c. An adhesive 503c may be located between the third segmented thermally conductive channel 502c and the fourth segmented thermally conductive channel 502d. It should be noted that an adhesive may not always be present between segmented thermally conductive channels and/or along the entire length of the segmented thermally conductive channels. Each of the segmented thermally conductive channel may be defined by a graphite sheet that has been cut.

In some implementations, each segmented thermally conductive channel (e.g., 502a, 502b, 502c, 502d) in the Y′ direction of the Y′-Z′ plane, has a thermal conductivity in a range of approximately 1000-1900 Watts per meter kelvin (W/(mk)). In some implementations, each segmented thermally conductive channel (e.g., 502a, 502b, 502c, 502d) in the Z′ direction, the Z′ direction of the X′-Z′ plane and/or the Z′ direction of the Y′-Z′ plane, has a thermal conductivity that is less than 30 Watts per meter kelvin (W/(mk)) (e.g., 3.5 W/(mk)). Each segmented thermally conductive channel may be a thermally anisotropic conductive channel (e.g., first thermally anisotropic conductive channel, second thermally anisotropic conductive channel, third thermally anisotropic conductive channel, fourth thermally anisotropic conductive channel). Each segmented thermally conductive channel may have a high thermal conductivity (e.g., high thermal conductivity value, relatively high thermal conductivity value, first directional thermal conductivity, first directional thermal conductivity value) along a length of the segmented thermally conductive channel. Each segmented thermally conductive channel may have a low thermal conductivity (e.g., low thermal conductivity value, relatively low thermal conductivity value, second directional thermal conductivity, second directional thermal conductivity value) along a width of the segmented thermally conductive channel. Each segmented thermally conductive channel may have a low thermal conductivity (e.g., low thermal conductivity value, relatively low thermal conductivity value, second directional thermal conductivity, second directional thermal conductivity value) between an adjacent and/or neighboring segmented thermally conductive channel. Thus, the thermal conductivity value between adjacent and/or neighboring thermally conductive channels (e.g., a first thermally conductive channel and a second thermally conductive channel) may be low and/or lower than the thermal conductivity value of the thermally conductive channel along the length of the thermally conductive channel.

In some implementations, each of the segmented thermally conductive channels 502 may have width in a range of about 25-50 micrometers. However, it is noted that the segmented thermally conductive channels 502 may have widths outside of the above mentioned range. In some implementations, the segmented thermally conductive channels 502 may have similar or different widths. The plurality of segmented thermally conductive channels 502 are configured so that heat transfer first primarily occurs along the length of the segmented thermally conductive channels, and initially little or no heat transfer occurs between neighboring segmented thermally conductive channels. However, over a period of time, there may be more heat transfer (e.g., heat dissipation) that occurs in other non-primary directions. The term “little or no heat transfer capabilities” in a particular direction may means that relative to heat transfer capabilities in a direction where there is maximum, primary and/or the most heat transfer capabilities, there is minimal or negligible heat transfer capabilities (e.g., heat transfer capabilities represents less than 5% of the heat transfer capabilities in a direction where there is maximum heat transfer capabilities) in that particular direction. The thickness or thinnest (in the X′ direction) of the thermally conductive layer 500 (relative to the length of thermally conductive layer and/or length of the segmented thermally conductive channel) makes it such that heat transfer (e.g., heat dissipation) will first mostly and primarily occur in the Y′ direction. For example, if there is a heat source located below the center of the thermally conductive layer 500, that heat will initially and mostly travel in the Y′ direction along the segmented thermally conductive channels 502, with some heat subsequently and/or eventually escaping and/or dissipating in the X′ direction and/or the Z′ direction. Heat transfer capabilities may be expressed in absolute terms and/or in relative terms. Heat transfer capabilities may be expressed through thermal conductivities values.

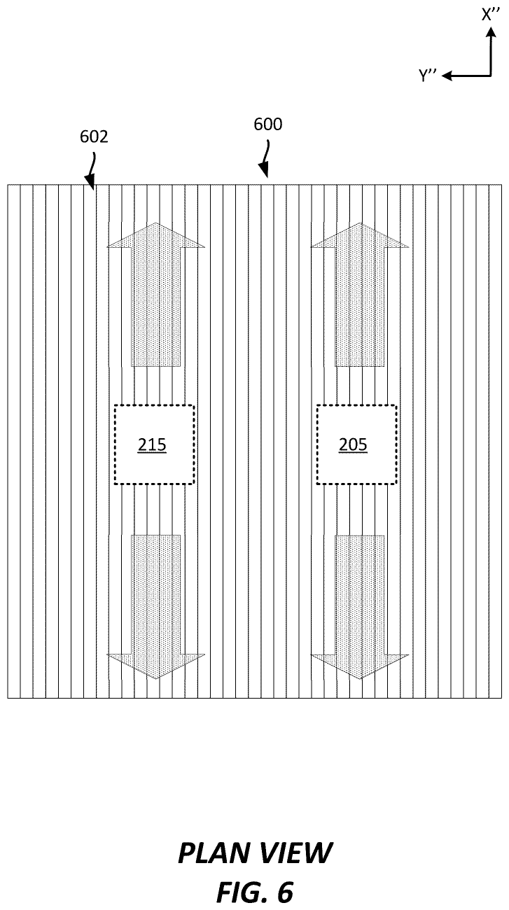

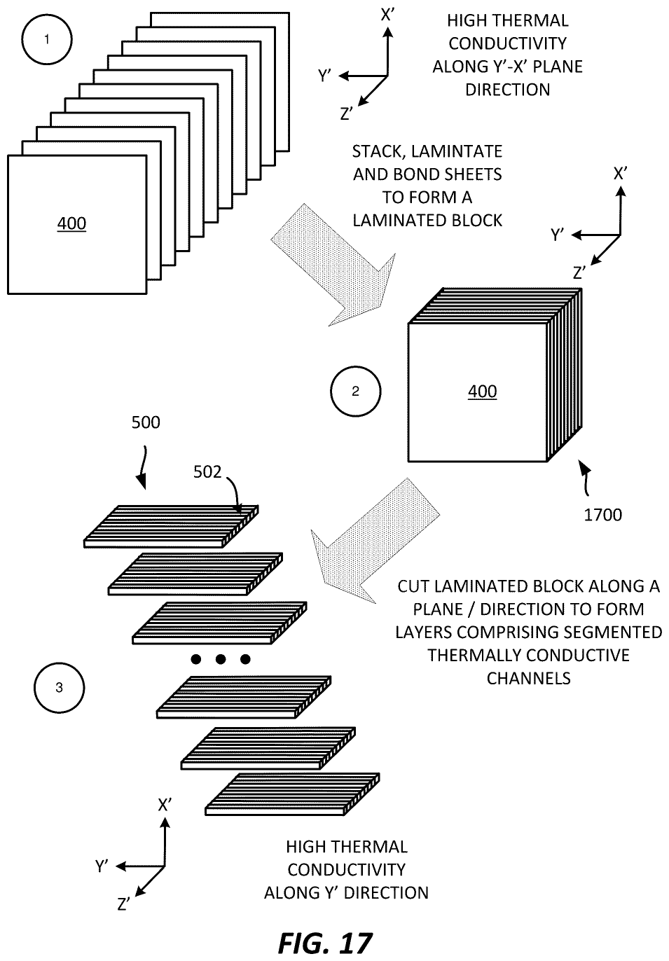

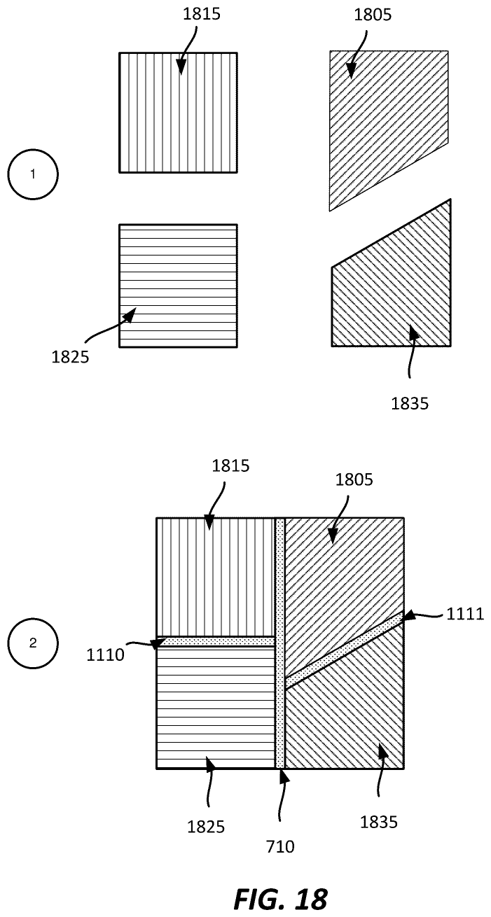

The thermally conductive layer 500 may be implemented in many configurations and/or implementations. FIGS. 6-12 illustrate examples of how the thermally conductive layer 500 may be implemented, combined and/or modified to provide different thermally conductive layers. Thus, the properties (e.g., anisotropic properties) described for the thermally conductive layer 500 and the thermally conductive channels 502 may also be applicable to any of the thermally conductive layers and/or any of the thermally conductive channels illustrated and described in at least FIGS. 6-12. Exemplary sequences for fabricating a thermally conductive layer comprising a plurality of segmented thermally conductive channels are described below in at least FIGS. 17-18.

FIG. 6 illustrates a plan view of a thermally conductive layer 600 that includes a plurality of segmented thermally conductive channels 602. The thermally conductive layer 600 is shown to be located over the integrated device 205 and the integrated device 215. The thermally conductive layer 600 is similar to the thermally conductive layer 500 of FIG. 5. The plurality of segmented thermally conductive channels 602 may be similar to the plurality of segmented thermally conductive channels 502. As shown in FIG. 6, the thermally conductive layer 600 is positioned over a region (of a device) that includes the integrated device 205 and/or the integrated device 215 in such a way that heat transfer (e.g., heat dissipation) first primarily occurs along the X″ direction of the X″-Y″ plane. The thermally conductive layer 600 may be coupled directly or indirectly to the integrated device 205 and/or the integrated device 215. As shown in FIG. 6, the length of the plurality of segmented thermally conductive channels 602 are aligned in the X″ direction of the X″-Y″ plane. In this configuration and/or arrangement, the plurality of segmented thermally conductive channels 602 are aligned in the X″ direction (e.g., first direction) of the X″-Y″ plane and the heat transfer first primarily occurs along the X″ direction of the X″-Y″ plane. This provides thermal decoupling between the integrated device 205 and the integrated device 215, as there is initially little or no heat transfer in the Y″ direction of the X″-Y″ plane. Thus, the thermally conductive layer 600 includes segmented thermally anisotropic conductive channels that are configured to (i) provide high thermal conductivity along a first direction (e.g., length of channels), and (ii) low thermal conductivity along another direction (e.g., width of channels, second direction).

It is noted that in the portion(s) of the thermally conductive layer 600 that is/are above the integrated device 205 and/or the integrated device 215, there may be heat transfer capabilities in the Z″ direction (which is perpendicular to both the Y″ direction and the X″ direction). In some implementations, two separate thermally conductive layers (e.g., 600) may be used, with each thermally conductive layer (e.g., 600) located above a respective integrated device. For example, a first thermally conductive layer (e.g., 600) may be located over the integrated device 205 and a second thermally conductive layer (e.g., 600) may be located over the integrated device 215.

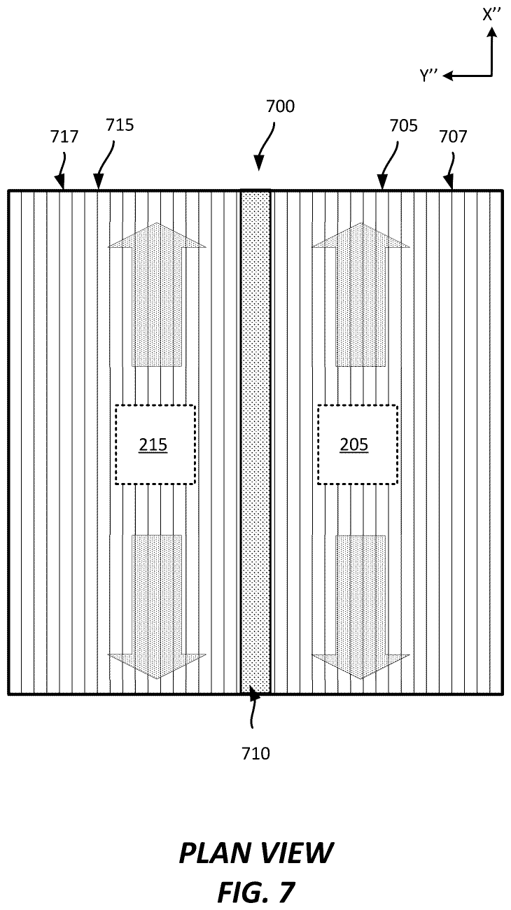

FIG. 7 illustrates a plan view of a thermally conductive layer 700 that includes a first portion 705, a second portion 715 and a thermally insulating material 710 (e.g., thermally insulating layer). The first portion 705 includes a first plurality of segmented thermally conductive channels 707 (e.g., segmented thermally anisotropic conductive channels). The second portion 715 includes a second plurality of segmented thermally conductive channels 717 (e.g., segmented thermally anisotropic conductive channels). The first portion 705 is coupled to the second portion 715 through the thermally insulating material 710. The thermally insulating material 710 may include aerogel. The thermally insulating material 710 may have a thermal conductivity of about 0.018 Watts per meter kelvin (W/(mk)). However, different implementations and/or different materials may have different thermal conductivity values. For example, the thermally insulating material 710 (and/or any thermally insulating material described in the disclosure) may have a thermal conductivity of 0.1 W/mk or less. A foam sponge is another example of a thermally insulating material. The first plurality of segmented thermally conductive channels 707 is coupled to the second plurality of segmented thermally conductive channels 717 through the thermally insulating material 710. An adhesive may be used to bond the first portion 705 to the thermally insulating material 710. Similarly, an adhesive may be used to bond the second portion 715 to the thermally insulating material 710. However, it is noted that other methods may be used to combine the first portion 705, the thermally insulating material 710 and the second portion 715. The first plurality of segmented thermally conductive channels 707 and the second plurality of segmented thermally conductive channels 717 are part of a plurality of segmented thermally conductive channels for the thermally conductive layer 700. The first plurality of segmented thermally conductive channels 707 and the second plurality of segmented thermally conductive channels 717 are aligned in the X″ direction of the X″-Y″ plane. Thus, the segmented thermally conductive channels 707 and 717, are configured to (i) provide high thermal conductivity along a first direction (e.g., length of channels), and (ii) low thermal conductivity along another direction (e.g., width of channels, second direction).

As shown in FIG. 7, the thermally conductive layer 700 is positioned over a region (of a device) that includes the integrated device 205 and/or the integrated device 215 in such a way that heat transfer (e.g., heat dissipation) first primarily occurs along the X″ direction of the X″-Y″ plane. The thermally conductive layer 700 may be coupled directly or indirectly to the integrated device 205 and/or the integrated device 215. The use of the thermally insulating material 710 helps improve thermal decoupling between the integrated device 205 and the integrated device 215, as the thermally insulating material 710 further helps reduce and/or eliminate heat transfer in the Y″ direction of the X″-Y″ plane. It is noted that in the portion(s) of the thermally conductive layer 700 that is above the integrated device 205 and/or the integrated device 215, there may be heat transfer capabilities in the Z″ direction (which is perpendicular to both the Y″ direction and the X″ direction).

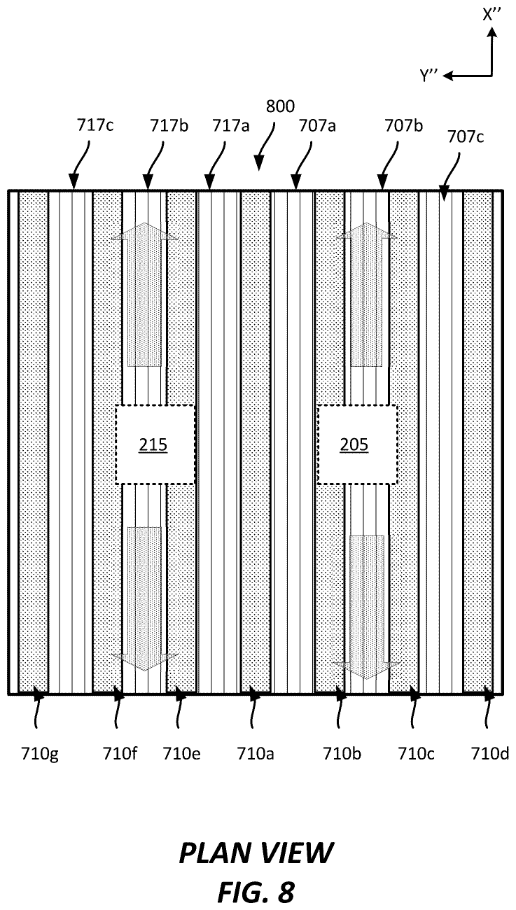

FIG. 8 illustrates a plan view of a thermally conductive layer 800 that includes alternating between segmented thermally conductive channels and thermally insulating materials. The thermally conductive layer 800 includes a plurality of segmented thermally conductive channels 707a, a plurality of segmented thermally conductive channels 707b, a plurality of segmented thermally conductive channels 707c, a plurality of segmented thermally conductive channels 717a, a plurality of segmented thermally conductive channels 717b, a plurality of segmented thermally conductive channels 717c, a thermally insulating material 710a, a thermally insulating material 710b, a thermally insulating material 710c, a thermally insulating material 710d, a thermally insulating material 710e, a thermally insulating material 710f, and a thermally insulating material 710g. An adhesive may be used to bond the plurality of segmented conductive channels and the thermally insulating material(s). The thermally insulating material (e.g., 710a-710g) may include aerogel.

The plurality of segmented thermally conductive channels 707a (e.g., segmented thermally anisotropic conductive channels), the plurality of segmented thermally conductive channels 707b (e.g., segmented thermally anisotropic conductive channels), the plurality of segmented thermally conductive channels 707c (e.g., segmented thermally anisotropic conductive channels), the plurality of segmented thermally conductive channels 717a (e.g., segmented thermally anisotropic conductive channels), the plurality of segmented thermally conductive channels 717b (e.g., segmented thermally anisotropic conductive channels), and/or the plurality of segmented thermally conductive channels 717c (e.g., segmented thermally anisotropic conductive channels) may be aligned in the X″ direction of the X″-Y″ plane.

The plurality of segmented thermally conductive channels 707a, the plurality of segmented thermally conductive channels 707b, the plurality of segmented thermally conductive channels 707c, the plurality of segmented thermally conductive channels 717a, the plurality of segmented thermally conductive channels 717b, and/or the plurality of segmented thermally conductive channels 717c may be configured to provide heat transfer primarily along the X″ direction of the X″-Y″ plane. Thus, the thermally conductive layer 800 includes segmented thermally anisotropic conductive channels that are configured to (i) provide high thermal conductivity along a first direction (e.g., length of channels), and (ii) low thermal conductivity along another direction (e.g., width of channels, second direction). The thermally conductive layer 800 may be coupled directly or indirectly to the integrated device 205 and/or the integrated device 215. The thermally conductive layer 800 may provide improved thermal decoupling between the integrated device 205 and the integrated device 215, through the use of additional thermally insulating materials. It is noted that in the portion(s) of the thermally conductive layer 800 that is above the integrated device 205 and/or the integrated device 215, there may be heat transfer capabilities in the Z″ direction (which is perpendicular to both the Y″ direction and the X″ direction).

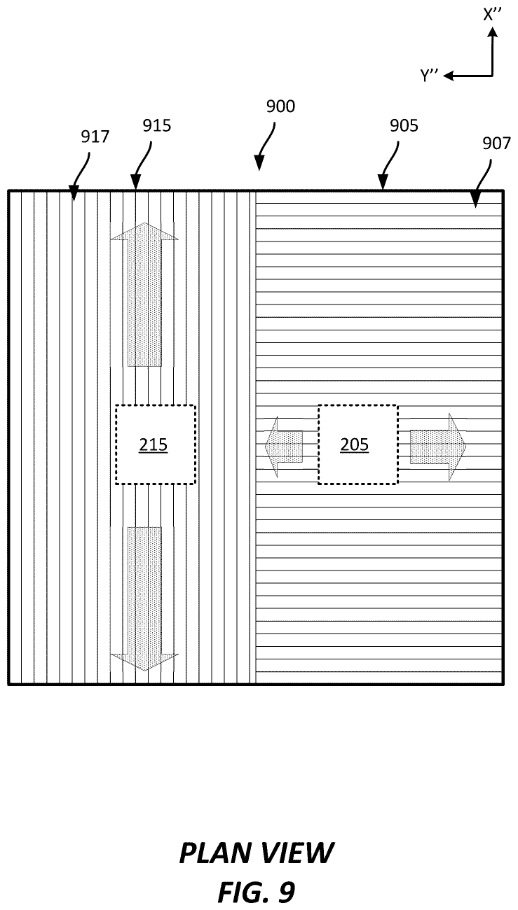

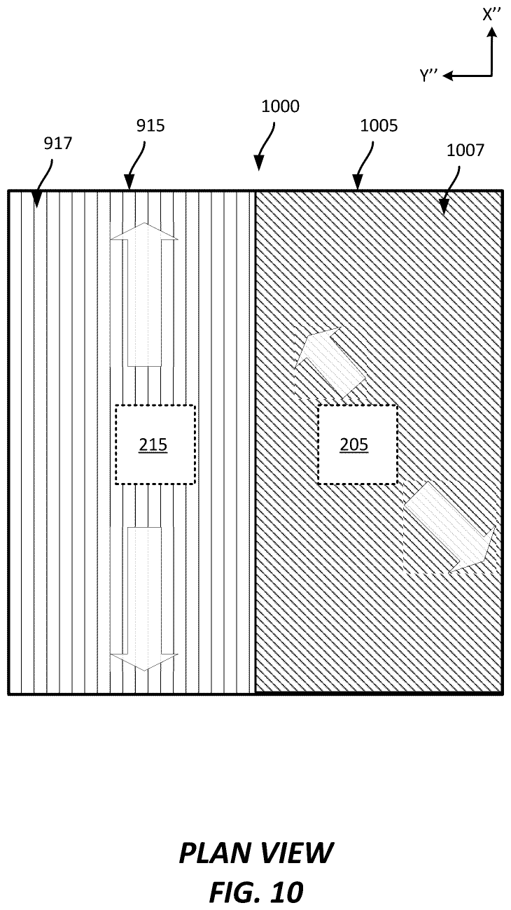

FIG. 9 illustrates a plan view of a thermally conductive layer 900 that includes a first thermally conductive layer 905, a second thermally conductive layer 915. The first thermally conductive layer 905 may be a first portion of the thermally conductive layer 900. The second thermally conductive layer 915 may be a second portion of the thermally conductive layer 900. Although not shown, the thermally conductive layer 900 may include a thermally insulating material (e.g., 710) between the first thermally conductive layer 905 and the second thermally conductive layer 915. The first thermally conductive layer 905 includes a first plurality of segmented thermally conductive channels 907 (e.g., segmented thermally anisotropic conductive channels). The second thermally conductive layer 915 includes a second plurality of segmented thermally conductive channels 917 (e.g., segmented thermally anisotropic conductive channels). The first thermally conductive layer 905 is coupled to the second thermally conductive layer 915 (e.g., through the use of an adhesive). In some implementations, the first thermally conductive layer 905 is coupled to the second thermally conductive layer 915 through the thermally insulating material 710.

The first plurality of segmented thermally conductive channels 907 and the second plurality of segmented thermally conductive channels 917 are part of a plurality of segmented thermally conductive channels for the thermally conductive layer 900. The first plurality of segmented thermally conductive channels 907 are aligned in the Y″ direction of the X″-Y″ plane. For example, the length of the first plurality of segmented thermally conductive channels 907 are aligned in the Y″ direction of the X″-Y″ plane. The first plurality of segmented thermally conductive channels 907 are configured to provide heat transfer first primarily (e.g., provide high first directional thermal conductivity value) along the Y″ direction of the X″-Y″ plane. The second plurality of segmented thermally conductive channels 917 are aligned in the X″ direction of the X″-Y″ plane. For example, the lengths of the second plurality of segmented thermally conductive channels 917 are aligned in the X″ direction of the X″-Y″ plane. The second plurality of segmented thermally conductive channels 917 are configured to provide heat transfer primarily (e.g., provide high second directional thermal conductivity value) along the X″ direction of the X″-Y″ plane. The Y″ direction (e.g., second direction) may be perpendicular relative to the X″ direction (e.g., first direction).

The segmented thermally conductive channels 907 are configured to (i) provide high thermal conductivity along a first direction (e.g., length of channels, Y″ direction), and (ii) low thermal conductivity along another direction (e.g., width of channels, second direction, X″ direction). The segmented thermally conductive channels 917 are configured to (i) provide high thermal conductivity along the second direction (e.g., length of channels, X″ direction), and (ii) low thermal conductivity along another direction (e.g., width of channels, first direction, Y″ direction).

This configuration and/or arrangement of a plurality of segmented thermally conductive channels may be used when heat transfer (e.g., heat dissipation) in a particular direction and/or towards a particular location is desired.

The thermally conductive layer 900 may be coupled directly or indirectly to the integrated device 205 and/or the integrated device 215. As shown in FIG. 9, the thermally conductive layer 900 is positioned over a region that includes the integrated device 205 and/or the integrated device 215 in such a way that (i) heat transfer (e.g., heat dissipation) first primarily occurs along the Y″ direction of the X″-Y″ plane in a first region that includes the integrated device 205 and (ii) heat transfer (e.g., heat dissipation) first primarily occurs along the X″ direction of the X″-Y″ plane in a second region that includes the integrated device 215. It is noted that in the portion(s) of the thermally conductive layer 900 that is above the integrated device 205 and/or the integrated device 215, there may be heat transfer capabilities in the Z″ direction (which is perpendicular to both the Y″ direction and the X″ direction).

FIG. 10 illustrates a plan view of a thermally conductive layer 1000 that includes a first thermally conductive layer 1005, a second thermally conductive layer 915. The first thermally conductive layer 1005 may be a first portion of the thermally conductive layer 1000. The second thermally conductive layer 915 may be a second portion of the thermally conductive layer 1000. Although not shown, the thermally conductive layer 1000 may include a thermally insulating material (e.g., 710) between the first thermally conductive layer 1005 and the second thermally conductive layer 915. The first thermally conductive layer 1005 includes a first plurality of segmented thermally conductive channels 1007 (e.g., segmented thermally anisotropic conductive channels). The second thermally conductive layer 915 includes a second plurality of segmented thermally conductive channels 917 (e.g., segmented thermally anisotropic conductive channels). The first thermally conductive layer 1005 is coupled to the second thermally conductive layer 915 (e.g., through the use of an adhesive). In some implementations, the first thermally conductive layer 1005 is coupled to the second thermally conductive layer 915 through the thermally insulating material 710.

The first plurality of segmented thermally conductive channels 1007 and the second plurality of segmented thermally conductive channels 917 are part of a plurality of segmented thermally conductive channels for the thermally conductive layer 1000. The first plurality of segmented thermally conductive channels 1007 are aligned in the diagonal direction of the X″-Y″ plane. For example, the lengths of the first plurality of segmented thermally conductive channels 1007 are aligned in the diagonal direction of the X″-Y″ plane. The first plurality of segmented thermally conductive channels 1007 are configured to provide heat transfer first primarily (e.g., provide high first directional thermal conductivity value) along a diagonal direction of the X″-Y″ plane. The second plurality of segmented thermally conductive channels 917 are aligned in the X″ direction of the X″-Y″ plane. For example, the lengths of the second plurality of segmented thermally conductive channels 917 are aligned in the X″ direction of the X″-Y″ plane. The second plurality of segmented thermally conductive channels 917 are configured to provide heat transfer first primarily (e.g., provide high second directional thermal conductivity value) along the X″ direction of the X″-Y″ plane. The diagonal direction (e.g., second direction) may be diagonal relative to the X″ direction (e.g., first direction).

The segmented thermally conductive channels 1007 are configured to (i) provide high thermal conductivity along a first direction (e.g., length of channels, diagonal direction), and (ii) low thermal conductivity along another direction (e.g., width of channels, second direction, another diagonal direction). The segmented thermally conductive channels 917 are configured to (i) provide high thermal conductivity along a third direction (e.g., length of channels, X″ direction), and (ii) low thermal conductivity along another direction (e.g., width of channels, fourth direction, Y″ direction).

This configuration and/or arrangement of a plurality of segmented thermally conductive channels may be used when heat transfer (e.g., heat dissipation) in a particular direction and/or towards a particular location is desired.

The thermally conductive layer 1000 may be coupled directly or indirectly to the integrated device 205 and/or the integrated device 215. As shown in FIG. 10, the thermally conductive layer 1000 is positioned over a region that includes the integrated device 205 and/or the integrated device 215 in such a way that (i) heat transfer (e.g., heat dissipation) first primarily occurs along a diagonal direction of the X″-Y″ plane in a first region that includes the integrated device 205 and (ii) heat transfer (e.g., heat dissipation) first primarily occurs along the X″ direction of the X″-Y″ plane in a second region that includes the integrated device 215. It is noted that in the portion(s) of the thermally conductive layer 1000 that is above the integrated device 205 and/or the integrated device 215, there may be heat transfer capabilities in the Z″ direction (which is perpendicular to both the Y″ direction and the X″ direction).

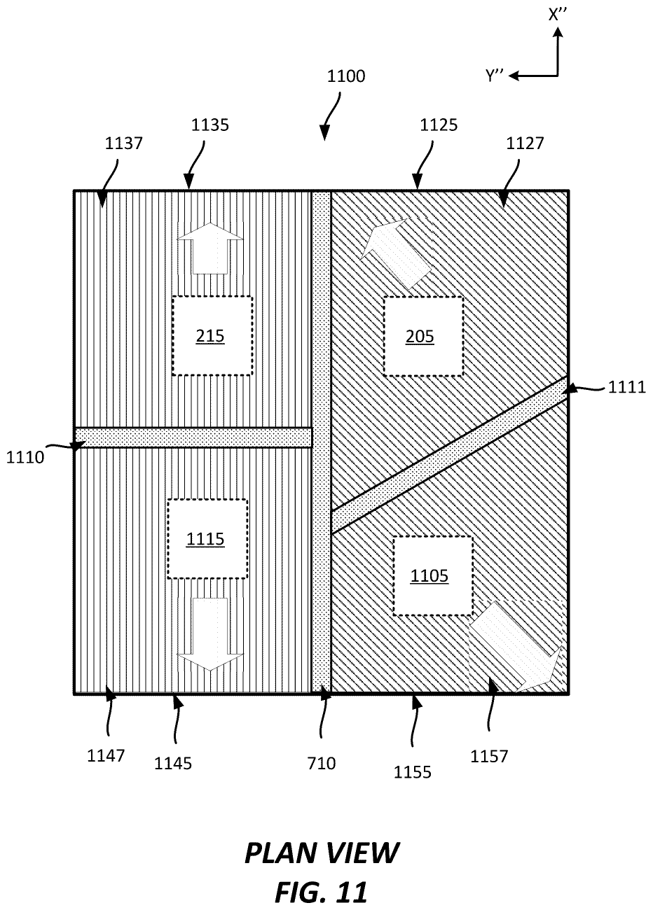

FIG. 11 illustrates a plan view of a thermally conductive layer 1100 that includes a first thermally conductive layer 1125, a second thermally conductive layer 1135, a third thermally conductive layer 1145, a fourth thermally conductive layer 1155, a thermally insulating material 710, a thermally insulating material 1110, and a thermally insulating material 1111. The first thermally conductive layer 1125 may be a first portion of the thermally conductive layer 1100. The second thermally conductive layer 1135 may be a second portion of the thermally conductive layer 1100. The third thermally conductive layer 1145 may be a third portion of the thermally conductive layer 1100. The fourth thermally conductive layer 1155 may be a fourth portion of the thermally conductive layer 1100. The first thermally conductive layer 1125 includes a first plurality of segmented thermally conductive channels 1127 (e.g., segmented thermally anisotropic conductive channels). The second thermally conductive layer 1135 includes a second plurality of segmented thermally conductive channels 1137 (e.g., segmented thermally anisotropic conductive channels). The third thermally conductive layer 1145 includes a third plurality of segmented thermally conductive channels 1147 (e.g., segmented thermally anisotropic conductive channels). The fourth thermally conductive layer 1155 includes a fourth plurality of segmented thermally conductive channels 1157 (e.g., segmented thermally anisotropic conductive channels). The first thermally conductive layer 1125 is coupled to the second thermally conductive layer 1135 and the third thermally conductive layer 1145 through the thermally insulating material 710. The second thermally conductive layer 1135 is coupled to the third thermally conductive layer 1145 through the thermally insulating material 1110. The first thermally conductive layer 1125 is coupled to the fourth thermally conductive layer 1155 through the thermally insulating material 1111. The third thermally conductive layer 1145 is coupled to the fourth thermally conductive layer 1155 through the thermally insulating material 710. It is noted that the thermally insulating material shown in FIG. 11 are optional. In some implementations, one portion of the thermally conductive layer 1100 may be coupled to another portion of the thermally conductive layer 1100 through an adhesive.

The first plurality of segmented thermally conductive channels 1127 are aligned in a first diagonal direction of the X″-Y″ plane. For example, the lengths of the first plurality of segmented thermally conductive channels 1127 are aligned in a first diagonal direction of the X″-Y″ plane. The first plurality of segmented thermally conductive channels 1127 are configured to provide heat transfer first primarily (e.g., provide high first directional thermal conductivity value) along the first diagonal direction of the X″-Y″ plane. The second plurality of segmented thermally conductive channels 1137 are aligned in the X″ direction of the X″-Y″ plane. For example, the lengths of the second plurality of segmented thermally conductive channels 1137 are aligned in the X″ direction of the X″-Y″ plane. The second plurality of segmented thermally conductive channels 1137 are configured to provide heat transfer first primarily (e.g., provide high second directional thermal conductivity value) along the X″ direction of the X″-Y″ plane. The third plurality of segmented thermally conductive channels 1147 are aligned in the X″ direction of the X″-Y″ plane. For example, the lengths of the third plurality of segmented thermally conductive channels 1147 are aligned in the X″ direction of the X″-Y″ plane. The third plurality of segmented thermally conductive channels 1147 are configured to provide heat transfer first primarily (e.g., provide high third directional thermal conductivity value) along the X″ direction of the X″-Y″ plane. The fourth plurality of segmented thermally conductive channels 1157 are aligned in a second diagonal direction of the X″-Y″ plane. For example, the lengths of the fourth plurality of segmented thermally conductive channels 1157 are aligned in a second diagonal direction of the X″-Y″ plane. The fourth plurality of segmented thermally conductive channels 1157 are configured to provide heat transfer first primarily (e.g., provide high fourth directional thermal conductivity value) along the second diagonal direction of the X″-Y″ plane. The second diagonal direction may be the same or a different direction than the first diagonal direction. The first diagonal direction (e.g., second direction) may be diagonal relative to the X″ direction (e.g., first direction) and/or the Y″ direction. The second diagonal direction (e.g., second direction) may be diagonal relative to the X″ direction (e.g., first direction) and/or the Y″ direction.

The segmented thermally conductive channels 1127 are configured to (i) provide high thermal conductivity along a first direction (e.g., length of channels, first diagonal direction), and (ii) low thermal conductivity along another direction (e.g., width of channels, second direction, second diagonal direction). The segmented thermally conductive channels 1137 are configured to (i) provide high thermal conductivity along the third direction (e.g., length of channels, X″ direction), and (ii) low thermal conductivity along another direction (e.g., width of channels, fourth direction, Y″ direction). The segmented thermally conductive channels 1147 are configured to (i) provide high thermal conductivity along the third direction (e.g., length of channels, X″ direction), and (ii) low thermal conductivity along another direction (e.g., width of channels, fourth direction, Y″ direction). The segmented thermally conductive channels 1157 are configured to (i) provide high thermal conductivity along the first direction (e.g., length of channels, first diagonal direction), and (ii) low thermal conductivity along another direction (e.g., width of channels, second direction, second diagonal direction).

This configuration and/or arrangement of a plurality of segmented thermally conductive channels may be used when heat transfer (e.g., heat dissipation) in a particular direction and/or towards a particular location is desired.

The thermally conductive layer 1100 may be coupled directly or indirectly to the integrated device 205, the integrated device 215, the component 1105 and/or the component 1115. As shown in FIG. 11, the thermally conductive layer 1000 is positioned over a region (of a device) that includes the integrated device 205, the integrated device 215, a component 1105 and a component 1115 in such a way that (i) heat transfer (e.g., heat dissipation) first primarily occurs along a first diagonal direction of the X″-Y″ plane in a first region that includes the integrated device 205, (ii) heat transfer (e.g., heat dissipation) first primarily occurs along the X″ direction of the X″-Y″ plane in a second region that includes the integrated device 215, (iii) heat transfer (e.g., heat dissipation) first primarily occurs along the X″ direction of the X″-Y″ plane in a third region that includes the component 1115, and (iv) heat transfer (e.g., heat dissipation) first primarily occurs along the first diagonal direction of the X″-Y″ plane in a fourth region that includes the component 1105. It is noted that in the portion(s) of the thermally conductive layer 1100 that is/are above the integrated device 205, the integrated device 215, the component 1105 and/or the component 1115, there may be heat transfer capabilities in the Z″ direction (which is perpendicular to both the Y″ direction and the X″ direction).

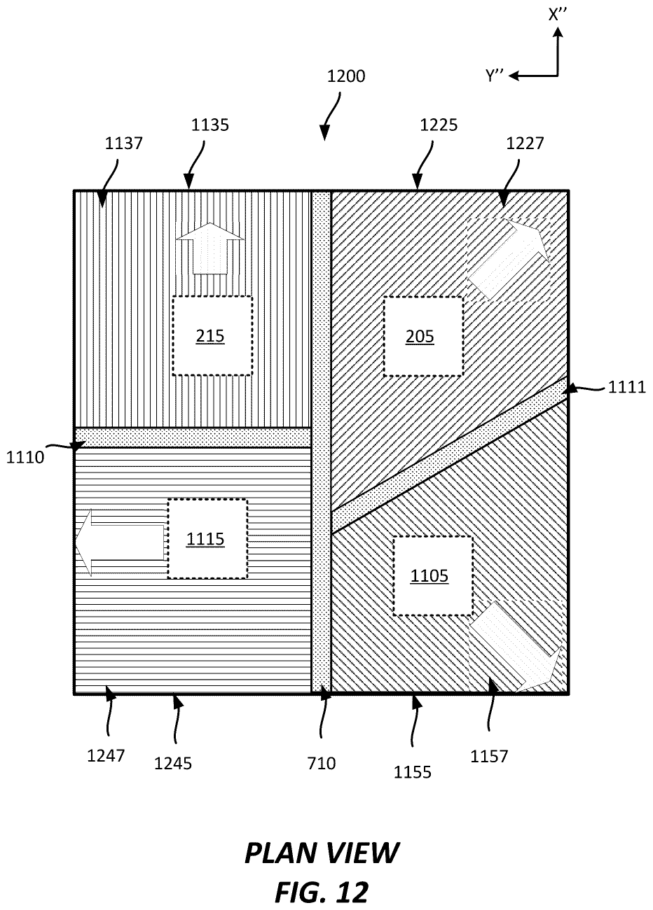

FIG. 12 illustrates a plan view of a thermally conductive layer 1200 that includes a first thermally conductive layer 1225, a second thermally conductive layer 1135, a third thermally conductive layer 1245, a fourth thermally conductive layer 1155, a thermally insulating material 710, a thermally insulating material 1110, and a thermally insulating material 1111. The first thermally conductive layer 1225 may be a first portion of the thermally conductive layer 1200. The second thermally conductive layer 1135 may be a second portion of the thermally conductive layer 1200. The third thermally conductive layer 1245 may be a third portion of the thermally conductive layer 1200. The fourth thermally conductive layer 1155 may be a fourth portion of the thermally conductive layer 1200. The first thermally conductive layer 1225 includes a first plurality of segmented thermally conductive channels 1227 (e.g., segmented thermally anisotropic conductive channels). The second thermally conductive layer 1135 includes a second plurality of segmented thermally conductive channels 1137 (e.g., segmented thermally anisotropic conductive channels). The third thermally conductive layer 1245 includes a third plurality of segmented thermally conductive channels 1247 (e.g., segmented thermally anisotropic conductive channels). The fourth thermally conductive layer 1155 includes a fourth plurality of segmented thermally conductive channels 1157 (e.g., segmented thermally anisotropic conductive channels). The first thermally conductive layer 1225 is coupled to the second thermally conductive layer 1135 and the third thermally conductive layer 1245 through the thermally insulating material 710. The second thermally conductive layer 1135 is coupled to the third thermally conductive layer 1245 through the thermally insulating material 1110. The first thermally conductive layer 1225 is coupled to the fourth thermally conductive layer 1155 through the thermally insulating material 1111. The third thermally conductive layer 1245 is coupled to the fourth thermally conductive layer 1155 through the thermally insulating material 710. It is noted that the thermally insulating material(s) shown in FIG. 12 is/are optional. In some implementations, one portion of the thermally conductive layer 1200 may be coupled to another portion of the thermally conductive layer 1200 through an adhesive.

The first plurality of segmented thermally conductive channels 1227 are aligned in a second diagonal direction of the X″-Y″ plane. For example, the lengths of the first plurality of segmented thermally conductive channels 1227 are aligned in the second diagonal direction of the X″-Y″ plane. The first plurality of segmented thermally conductive channels 1227 are configured to provide heat transfer first primarily (e.g., provide high first directional thermal conductivity value) along the second diagonal direction of the X″-Y″ plane. The second plurality of segmented thermally conductive channels 1137 are aligned in the X″ direction of the X″-Y″ plane. For example, the lengths of the second plurality of segmented thermally conductive channels 1137 are aligned in the X″ direction of the X″-Y″ plane. The second plurality of segmented thermally conductive channels 1137 are configured to provide heat transfer first primarily (e.g., provide high second directional thermal conductivity value) along the X″ direction of the X″-Y″ plane. The third plurality of segmented thermally conductive channels 1247 are aligned in the Y″ direction of the X″-Y″ plane. For example, the lengths of the third plurality of segmented thermally conductive channels 1247 are aligned in the Y″ direction of the X″-Y″ plane. The third plurality of segmented thermally conductive channels 1247 are configured to provide heat transfer first primarily (e.g., provide high third directional thermal conductivity value) along the Y″ direction of the X″-Y″ plane. The fourth plurality of segmented thermally conductive channels 1157 are aligned in a first diagonal direction of the X″-Y″ plane. For example, the lengths of the fourth plurality of segmented thermally conductive channels 1157 are aligned in the first diagonal direction of the X″-Y″ plane. The fourth plurality of segmented thermally conductive channels 1157 are configured to provide heat transfer first primarily (e.g., provide high fourth directional thermal conductivity value) along the first diagonal direction of the X″-Y″ plane. The second diagonal direction may be a different direction than the first diagonal direction. The first diagonal direction and/or the second diagonal direction may be diagonal relative to the X″ direction and/or the Y″ direction.

The segmented thermally conductive channels 1227 are configured to (i) provide high thermal conductivity along a second direction (e.g., length of channels, second diagonal direction), and (ii) low thermal conductivity along another direction (e.g., width of channels, first direction, first diagonal direction). The segmented thermally conductive channels 1137 are configured to (i) provide high thermal conductivity along a third direction (e.g., length of channels, X″ direction), and (ii) low thermal conductivity along another direction (e.g., width of channels, fourth direction, Y″ direction). The segmented thermally conductive channels 1247 are configured to (i) provide high thermal conductivity along the fourth direction (e.g., length of channels, Y″ direction), and (ii) low thermal conductivity along another direction (e.g., width of channels, third direction, X″ direction). The segmented thermally conductive channels 1157 are configured to (i) provide high thermal conductivity along the first direction (e.g., length of channels, first diagonal direction), and (ii) low thermal conductivity along another direction (e.g., width of channels, second direction, second diagonal direction).

This configuration and/or arrangement of a plurality of segmented thermally conductive channels may be used when heat transfer (e.g., heat dissipation) in a particular direction and/or towards a particular location is desired.

The thermally conductive layer 1200 may be coupled directly or indirectly to the integrated device 205, the integrated device 215, the component 1105 and/or the component 1115. As shown in FIG. 12, the thermally conductive layer 1000 is positioned over a region that includes the integrated device 205, the integrated device 215, a component 1105 and a component 1115 in such a way that (i) heat transfer (e.g., heat dissipation) first primarily occurs along a second diagonal direction of the X″-Y″ plane in a first region that includes the integrated device 205, (ii) heat transfer (e.g., heat dissipation) first primarily occurs along the X″ direction of the X″-Y″ plane in a second region that includes the integrated device 215, (iii) heat transfer (e.g., heat dissipation) first primarily occurs along the Y″ direction of the X″-Y″ plane in a third region that includes the component 1115, and (iv) heat transfer (e.g., heat dissipation) first primarily occurs along a first diagonal direction of the X″-Y″ plane in a fourth region that includes the component 1105. It is noted that in the portion(s) of the thermally conductive layer 1200 that is/are above the integrated device 205, the integrated device 215, the component 1105 and/or the component 1115, there may be heat transfer capabilities in the Z″ direction (which is perpendicular to both the Y″ direction and the X″ direction).

It is noted that the use of the term direction (e.g., X″ direction, Y″ direction, X′ direction, Y′ direction) in the disclosure may mean a positive direction and/or a negative direction. The thermally conductive layers comprising segmented thermally conductive channels in FIGS. 5-12 may be used instead of or in conjunction with the thermally conductive layer 330 of FIG. 3. FIGS. 6-12 illustrate how a thermally conductive layer that includes segmented thermally conductive channels may be used to control how and/or where heat dissipates in a device. It is noted that other implementations may use other configurations and/or arrangements of segmented thermally anisotropic conductive channels.

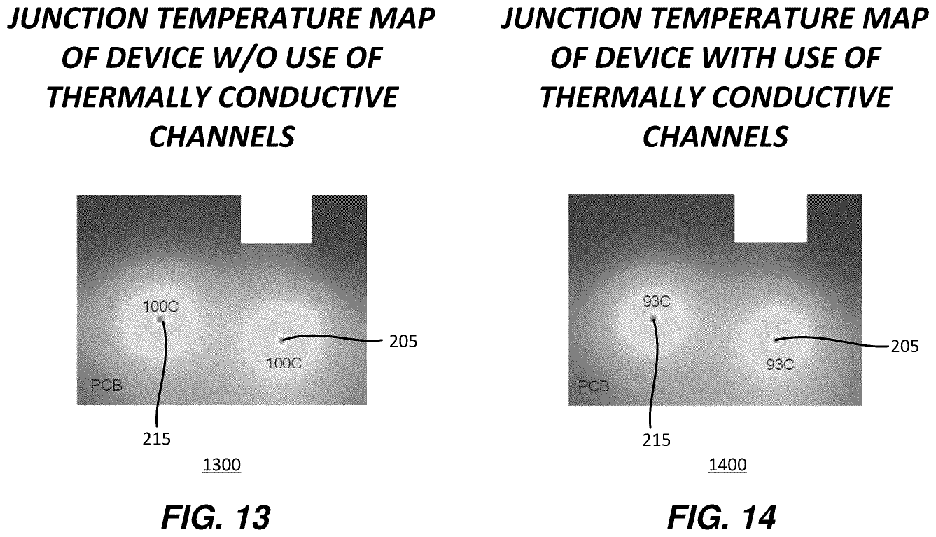

FIGS. 13 and 14 illustrate exemplary temperature maps and/or heat maps that show temperatures at junction points of components configured to generate heat. FIG. 13 illustrates an exemplary junction temperature map 1300 for a device that does not include a thermally conductive layer comprising a plurality of segmented thermally conductive channels. The junction temperature map 1300 includes a junction temperature at the integrated device 205 and a junction temperature at the integrated device 215. As shown in FIG. 13, when a device does not include a thermally conductive layer comprising a plurality of segmented thermally conductive channels, the junction temperature at the integrated device 205 and the junction temperature at the integrated device 215 may reach 100 degrees Celsius.

FIG. 14 illustrates an exemplary junction temperature map 1400 for a device that includes a thermally conductive layer comprising a plurality of segmented thermally conductive channels. The junction temperature map 1400 includes a junction temperature at the integrated device 205 and a junction temperature at the integrated device 215. As shown in FIG. 14, when a device includes a thermally conductive layer comprising a plurality of segmented thermally conductive channels, the junction temperature at the integrated device 205 and the junction temperature at the integrated device 215 may reach 93 degrees Celsius.

Thus, as shown in FIGS. 13 and 14, the use of a thermally conductive layer comprising a plurality of segmented thermally conductive channels (e.g., segmented thermally anisotropic conductive channels) helps decrease the junction temperature of the integrated devices, which helps prevent the integrated devices from overheating. This can lead to better performance of the integrated devices and/or the devices that include these integrated devices.

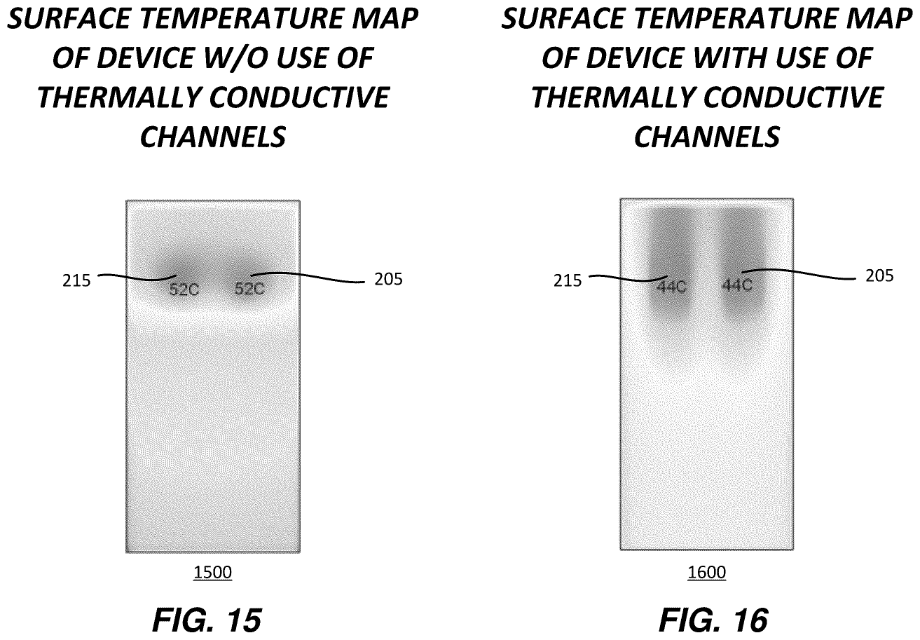

FIGS. 15 and 16 illustrate exemplary temperature maps and/or heat maps that show temperatures on display points of a device. FIG. 15 illustrates an exemplary display surface temperature map 1500 for a device that does not include a thermally conductive layer comprising a plurality of segmented thermally conductive channels. The display surface temperature map 1500 includes a display surface temperature above the integrated device 205 and a display surface temperature above the integrated device 215. As shown in FIG. 15, when a device does not include a thermally conductive layer comprising a plurality of segmented thermally conductive channels, the display surface temperature above the integrated device 205 and the display surface temperature above the integrated device 215 may reach 52 degrees Celsius.

FIG. 16 illustrates an exemplary display surface temperature map 1600 for a device that includes a thermally conductive layer comprising a plurality of segmented thermally conductive channels. The display surface temperature map 1600 includes a display surface temperature above the integrated device 205 and a display surface temperature above the integrated device 215. FIG. 15 illustrates how display surface temperatures may be reduced through the use of a thermally conductive layer that includes a plurality of segmented thermally conductive channels (e.g., segmented thermally anisotropic conductive channels). As shown in FIG. 16, when a device includes a thermally conductive layer comprising a plurality of segmented thermally conductive channels, the display surface temperature over the integrated device 205 and the display surface temperature over the integrated device 215 may reach 44 degrees Celsius. FIG. 16 illustrates more of the heat generated by the integrated device 205 and the integrated device 215 spread over a larger surface through the help of the thermally conductive channels, which helps reduce the surface temperature (e.g., display surface temperature) of the device. FIG. 16 also illustrates how thermally conductive channels help thermally decouple two neighboring integrated devices. The thermally conductive channels help channel the heat away from the other neighboring integrated devices.

Thus, as shown in FIGS. 15 and 16, the use of a thermally conductive layer comprising a plurality of segmented thermally conductive channels helps (e.g., segmented thermally anisotropic conductive channels) decrease the display surface temperature of the device, which helps make the device more comfortable to hold and handle. It is noted that the illustrations of FIGS. 13-16 are merely exemplary. The numerical values used in FIGS. 13-16 are exemplary, and are used to illustrate the performance advantage of the thermally conductive layer that includes a plurality of segmented thermally conductive channels. Different implementations may provide different results and performances in the heat maps and temperature maps, depending on the use, the location, the configuration, the size, the shape and/or the arrangement of the thermally conductive layer that includes a plurality of segmented thermally conductive channels.

### Exemplary Sequence for Fabricating a Thermally Conductive Layer Comprising Thermally Conductive Channels

FIG. 17 illustrates an exemplary sequence for providing or fabricating a thermally conductive layer comprising thermally conductive channels. In some implementations, the sequence of FIG. 17 may be used to provide or fabricate the thermally conductive layer 500 described in the disclosure.

It should be noted that the sequence of FIG. 17 may combine one or more stages in order to simplify and/or clarify the sequence for providing or fabricating a thermally conductive layer. In some implementations, the order of the processes may be changed or modified. In some implementations, one or more of processes may be replaced or substituted without departing from the spirit of the disclosure.

Stage 1, as shown in FIG. 17, illustrates a state after a plurality of thermally conductive sheets 400 are provided. The plurality of thermally conductive sheets 400 include graphite (e.g., graphite sheet). Each thermally conductive sheet 400 may be thermally anisotropic conductive along a plane. The thermally conductive sheet 400 is configured to provide heat transfer capabilities (e.g., dissipate heat) primarily along a plane (e.g., X′-Y′ plane). There is little or no heat transfer capabilities in the Z′ direction.

Stage 2 illustrates a state after the plurality of thermally conductive layers are stacked, laminated and bonded to form a laminated block of thermally conductive sheets 1700. At least one adhesive may be used to bond the plurality of thermally conductive sheets together to form the laminated block of thermally conductive sheets 1700. The laminated block of thermally conductive sheets 1700 is configured to provide heat transfer capabilities (e.g., dissipate heat) primarily along a plane (e.g., X′-Y′ plane). There is little or no heat transfer capabilities in the Z′ direction. Each sheet from the laminated block of thermally conductive sheets 1700 is configured to provide heat transfer capabilities (e.g., dissipate heat) primarily along a plane (e.g., X′-Y′ plane).

Stage 3 illustrates a state after the laminated block of thermally conductive sheets 1700 is cut (e.g., sliced) to form individual thermally conductive layers 500 comprising a plurality of segmented thermally conductive channels 502. The laminated block of thermally conductive sheets 1700 is cut along various Y′-Z′ plane of the laminated block of thermally conductive sheets 1700 to form the individual thermally conductive layers 500. The plurality of segmented thermally conductive channels 502 may be co-planar to each other. The plurality of segmented thermally conductive channels 502 are aligned in the Y′ direction. For example, the lengths of the plurality of segmented thermally conductive channels 502 are aligned in the Y′ direction. The plurality of segmented thermally conductive channels 502 are configured to provide heat transfer capabilities (e.g., dissipate heat) first primarily (e.g., provide high heat thermal conductivity value) along the Y′ direction and/or along the lengths of the plurality of segmented thermally conductive channels 502. The thermally conductive layer 500 includes segmented thermally conductive channels 502 that are configured to (i) provide high thermal conductivity along a first direction (e.g., length of channels, Y′ direction), and (ii) low thermal conductivity along another direction (e.g., width of channels, second direction, Z′ direction).

### Exemplary Sequence for Fabricating a Thermally Conductive Layer Comprising Thermally Conductive Channels

FIG. 18 illustrates an exemplary sequence for providing or fabricating a thermally conductive layer comprising thermally conductive channels aligned in different directions. In some implementations, the sequence of FIG. 18 may be used to provide or fabricate the thermally conductive layer 1200 described in the disclosure. However, the sequence of FIG. 18 may be used to provide any of the thermally conductive layers described in the disclosure.

It should be noted that the sequence of FIG. 18 may combine one or more stages in order to simplify and/or clarify the sequence for providing or fabricating a thermally conductive layer. In some implementations, the order of the processes may be changed or modified. In some implementations, one or more of processes may be replaced or substituted without departing from the spirit of the disclosure.

Stage 1, as shown in FIG. 18, illustrates a state after several thermally conductive layers (e.g., 1815, 1805, 1835, 1825) are provided. Each thermally conductive layers includes a plurality of segmented thermally anisotropic conductive channels that are aligned in a different direction (e.g., first direction, second direction, first diagonal direction, second diagonal direction). In some implementations, some of the thermally conductive layers may include thermally conductive channels that are aligned in the same directions as thermally conductive channels from other thermally conductive layers. The thermally conductive layers may have the same, similar and/or different shapes and/or sizes. FIG. 18 illustrates an example of fabricating thermally conductive layers comprising a plurality of segmented thermally anisotropic conductive channels.

Stage 2 illustrates a state after the several layers have been combined through the use of thermally insulating materials. The first thermally conductive layer 1805 is coupled to the second thermally conductive layer 1815 and the third thermally conductive layer 1825 through the thermally insulating material 710. The second thermally conductive layer 1815 is coupled to the third thermally conductive layer 1825 through the thermally insulating material 1110. The first thermally conductive layer 1205 is coupled to the fourth thermally conductive layer 1835 through the thermally insulating material 1111. The third thermally conductive layer 1825 is coupled to the fourth thermally conductive layer 1835 through the thermally insulating material 710. It is noted that the thermally insulating material shown are optional. In some implementations, one portion of the thermally conductive layer may be coupled to another portion of the thermally conductive layer and/or a thermally insulating material through an adhesive (e.g., glue, bonding agent). It is noted other methods and/or materials may be used to couple one portion of the thermally conductive layer to another portion of the thermally conductive layer and/or a thermally insulating material.

### Exemplary Flow Diagram of a Method for Coupling a Thermally Conductive Layer Comprising Thermally Conductive Channels

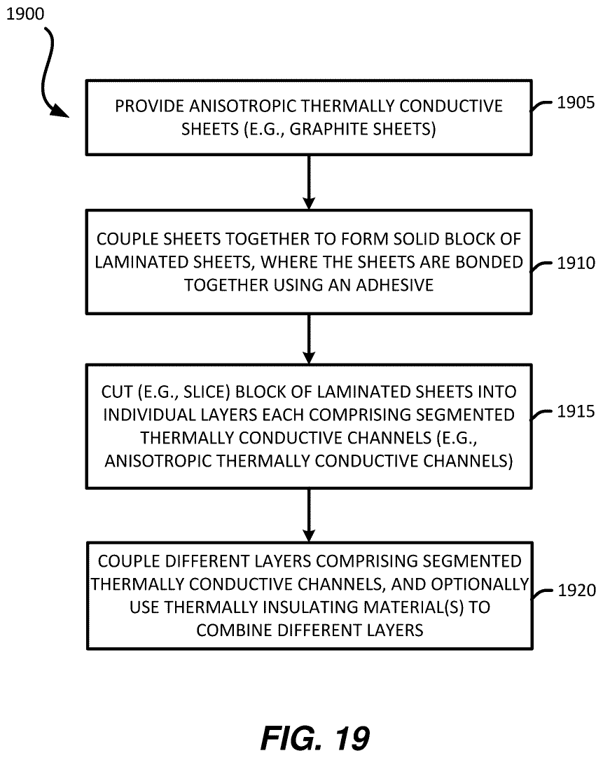

FIG. 19 illustrates an exemplary flow diagram of a method 1900 for fabricating a thermally conductive layer comprising a plurality of segmented thermally conductive channels. In some implementations, the method 1900 of FIG. 19 may be used to fabricate the thermally conductive layer 1200. However, the method 1900 may be used to fabricate any of the thermally conductive layers described in the disclosure.

It should be noted that the method 1900 of FIG. 19 may combine one or more processes in order to simplify and/or clarify the method for fabricating a thermally conductive layers. In some implementations, the order of the processes may be changed or modified.

The method provides (at 1905) a plurality of thermally conductive sheets 400 (e.g., thermally anisotropic conductive sheets). The plurality of thermally conductive sheets 400 include graphite (e.g., graphite layer). Each thermally conductive sheet 400 may be thermally anisotropic conductive along a plane. The thermally conductive sheet 400 is configured to provide heat transfer capabilities (e.g., dissipate heat) first primarily along a plane (e.g., X′-Y′ plane). The thermally conductive layer has little or no heat transfer capabilities in the Z′ direction. Stage 1 of FIG. 17 illustrates an example of a plurality of thermally conductive layers.

The method couples (at 1910) the plurality of thermally conductive sheets through the use of stacking, lamination and bonding to form a laminated block of thermally conductive sheets 1700. At least one adhesive may be used to bond the plurality of thermally conductive sheets together to form the laminated block of thermally conductive sheets 1700. The laminated block of thermally conductive sheets 1700 is configured to provide heat transfer capabilities (e.g., dissipate heat) first primarily along a plane (e.g., X′-Y′ plane). The laminated block of thermally conductive sheets 1700 has little or no heat transfer capabilities in the Z′ direction. Each layer from the laminated block of thermally conductive sheets 1700 is configured to provide heat transfer capabilities (e.g., dissipate heat) first primarily along a plane (e.g., X′-Y′ plane). Stage 2 of FIG. 17 illustrates an example of a laminated block of thermally conductive sheets.

The method cuts (at 1915) the laminated block of thermally conductive sheets 1700 into individual thermally conductive layers 500 comprising a plurality of segmented thermally conductive channels 502. The laminated block of thermally conductive sheets 1700 is cut along various Y′-Z′ planes of the laminated block of thermally conductive sheets 1700 to form the individual thermally conductive layers 500. The plurality of segmented thermally conductive channels 502 are aligned in the Y′ direction. The plurality of segmented thermally conductive channels 502 are configured to provide heat transfer capabilities (e.g., dissipate heat) first primarily along the Y′ direction. Stage 3 of FIG. 17 illustrates an example of a plurality of segmented thermally conductive channels.

The method couples (at 1920) several layers through the use of thermally insulating materials. For example, a first thermally conductive layer 1225 is coupled to a second thermally conductive layer 1135 and a third thermally conductive layer 1245 through a thermally insulating material 710. A second thermally conductive layer 1135 is coupled to a third thermally conductive layer 1245 through a thermally insulating material 1110. The first thermally conductive layer 1225 is coupled to a fourth thermally conductive layer 1155 through the thermally insulating material 1111. The third thermally conductive layer 1245 is coupled to the fourth thermally conductive layer 1155 through the thermally insulating material 710. It is noted that the thermally insulating material shown are optional. In some implementations, one portion of the thermally conductive layer may be coupled to another portion of the thermally conductive layer and/or a thermally insulating material through an adhesive. It is noted that the use of one or more thermally insulating materials is optional. Stage 2 of FIG. 18 illustrates an example of coupling different layers together.

It is noted that in the disclosure, numerous coordinate systems (X-Y-Z, X′-Y′-Z′, X″-Y″-Z″) are used and described. These exemplary coordinate systems are used to help explain the anisotropic thermal properties of the thermally conductive layer and/or the segmented thermally conductive channels. These different coordinate systems may be independent of each other or they may be related to one or more coordinate systems. Other coordinate systems may be used to illustrate direction, orientation and/or alignment.

### Exemplary Electronic Devices

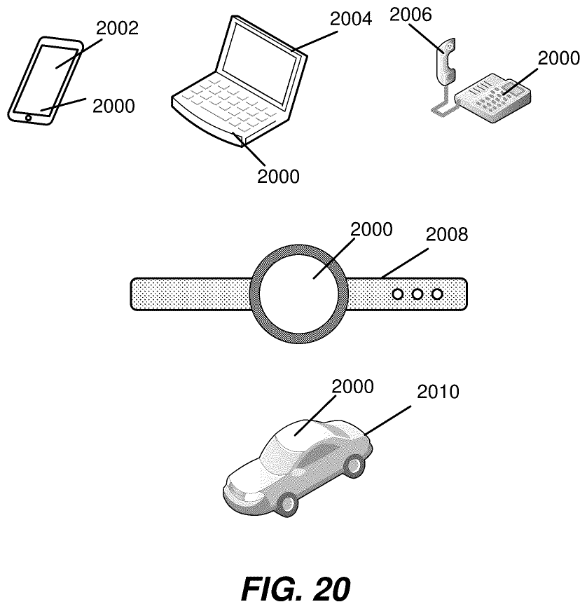

FIG. 20 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 2002, a laptop computer device 2004, a fixed location terminal device 2006, a wearable device 2008, or automotive vehicle 2010 may include a device 2000 as described herein. The device 2000 may be, for example, any of the devices and/or integrated circuit (IC) packages described herein. The devices 2002, 2004, 2006 and 2008 and the vehicle 2010 illustrated in FIG. 20 are merely exemplary. Other electronic devices may also feature the device 2000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 3-12 and/or 17-20 may be rearranged and/or combined into a single component, process, feature or function or embodied in several components, processes, or functions. Additional elements, components, processes, and/or functions may also be added without departing from the disclosure. It should also be noted FIGS. 3-12 and/or 17-20 and its corresponding description in the present disclosure is not limited to dies and/or ICs. In some implementations, FIGS. 3-12 and/or 17-20 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. Electromagnetic coupling may mean that a signal from one circuit and/or component affects a signal of another circuit and/or component. Electromagnetic coupling may cause crosstalk. Electromagnetic coupling may be a form of signal coupling. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “encapsulating” means that the object may partially encapsulate or completely encapsulate another object. The term “surrounding” means that an object(s) may partially surround or completely surround another object. The term “extends through” means that the object may partially extend or completely extend through another object. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect may include an electrically conductive material that may be configured to provide an electrical path for a signal (e.g., a data signal), ground and/or power. An interconnect may be part of a circuit. An interconnect may include more than one element or component. An interconnect may be defined by one or more interconnects. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A device comprising a region that includes a component configured to generate heat; and a thermally conductive layer coupled to the region, wherein the thermally conductive layer includes a plurality of segmented thermally anisotropic conductive channels.

Aspect 2: The device of aspect 1, wherein at least one segmented thermally anisotropic conductive channel from the plurality of segmented thermally anisotropic conductive channels is aligned in a first direction.

Aspect 3: The device of aspect 2, wherein each segmented thermally anisotropic conductive channel from the plurality of segmented thermally anisotropic conductive channels is configured to provide a high thermal conductivity in the first direction and a low thermal conductivity in a second direction.

Aspect 4: The device of aspects 2 through 3, wherein the thermally conductive layer includes at least one adhesive that bonds the plurality of segmented thermally anisotropic conductive channels.

Aspect 5: The device of aspect 4, wherein the plurality of segmented thermally anisotropic conductive channels includes a first segmented thermally anisotropic conductive channel and a second segmented thermally anisotropic conductive channel, and wherein the at least one adhesive is located between at least the first segmented thermally anisotropic conductive channel and the second segmented thermally anisotropic conductive channel.

Aspect 6: The device of aspect 1, wherein a first plurality of segmented thermally anisotropic conductive channels from the plurality of segmented thermally anisotropic conductive channels are aligned in a first direction, and wherein a second plurality of segmented thermally anisotropic conductive channels from the plurality of segmented thermally anisotropic conductive channels are aligned in a second direction.

Aspect 7: The device of aspect 6, wherein each segmented thermally anisotropic conductive channel from the first plurality of segmented thermally anisotropic conductive channels is configured to provide a high first thermal conductivity value in the first direction, and wherein each segmented thermally anisotropic conductive channel from the second plurality of segmented thermally anisotropic conductive channels is configured to provide a high second thermal conductivity value in the second direction.

Aspect 8: The device of aspects 6 through 7, wherein the second direction is perpendicular to the first direction.

Aspect 9: The device of aspects 6 through 7, wherein the second direction is diagonal to the first direction.

Aspect 10: The device of aspect 1, wherein a segmented thermally anisotropic conductive channel from the plurality of segmented thermally anisotropic conductive channels is configured to provide a high thermal conductivity along a length of the segmented thermally conductive channel.

Aspect 11: The device of aspect 10, wherein the thermally anisotropic conductive channel includes a thermally anisotropic conductive material that is configured to provide the high thermal conductivity along a first direction.

Aspect 12: The device of aspect 11, wherein the thermally anisotropic conductive material has a high thermal conductivity value in the first direction, and wherein the thermally anisotropic conductive material has a low thermal conductivity value in at least a second direction.

Aspect 13: The device of aspect 12, wherein the first direction is along the length of the thermally anisotropic conductive channel, and wherein the second direction is along a width of the thermally anisotropic conductive channel.

Aspect 14: The device of aspects 12 through 13, wherein the thermally conductive material includes a thermal conductivity value in the first direction that is in a range of approximately 1000-1900 Watts per meter kelvin (W/(mk)), and wherein the thermally conductive material includes a thermal conductivity value in the second direction that is less than 30 Watts per meter kelvin (W/(mk)).

Aspect 15: The device of aspect 1, wherein the thermally conductive layer comprises a first portion comprising a first plurality of segmented thermally anisotropic conductive channels from the plurality of segmented thermally anisotropic conductive channels; a second portion comprising a second plurality of segmented thermally anisotropic conductive channels from the plurality of segmented thermally anisotropic conductive channels; and a thermally insulating material coupled to the first portion and the second portion.

Aspect 16: The device of aspect 15, wherein the first plurality of segmented thermally anisotropic conductive channels are aligned in a first direction, and wherein the second plurality of segmented thermally anisotropic conductive channels are aligned in a second direction.

Aspect 17: The device of aspects 15 through 16, wherein the thermally insulating material includes aerogel, and/or wherein the thermally conductive layer includes graphite.

Aspect 18: The device of aspects 1 through 17, wherein the region includes a first integrated device, wherein the component includes a second integrated device, and wherein the thermally conductive layer is configured to thermally decouple the first integrated device from the second integrated device.

Aspect 19: The device of aspects 1 through 18, wherein the device is configured to provide Wireless Fidelity (WiFi) communication and/or cellular communication, wherein the thermally conductive layer that includes the plurality of segmented thermally conductive channels is configured to reduce the junction temperature of the component, and wherein the thermally conductive layer that includes the plurality of segmented thermally conductive channels is further configured to reduce a surface temperature of the device.

Aspect 20: The device of aspects 1 through 19, wherein the device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A device comprising a region that includes a first integrated device configured to generate heat; and a second integrated device configured to generate heat. The device includes means for segmented anisotropic heat transfer coupled to the region.

Aspect 22: The device of aspect 21, wherein the means for segmented anisotropic heat transfer includes a plurality of thermally anisotropic conductive channels aligned in a first direction, and wherein each thermally anisotropic conductive channel from the plurality of thermally anisotropic conductive channels is configured to provide high heat transfer capabilities in the first direction and low heat transfer capabilities in a direction parallel to a width of the thermally anisotropic conductive channel.

Aspect 23: The device of aspect 21, wherein the means for segmented anisotropic heat transfer comprises: a plurality of first thermally anisotropic conductive channels aligned in a first direction, and a plurality of second thermally anisotropic conductive channels aligned in a second direction, wherein each first thermally anisotropic conductive channel from the plurality of first thermally anisotropic conductive channels is configured to provide high heat transfer capabilities along a length of the first thermally anisotropic conductive channel, and wherein each second thermally anisotropic conductive channel from the plurality of second thermally anisotropic conductive channels is configured to provide high heat transfer capabilities along a length of the second thermally anisotropic conductive channel.

Aspect 24: The device of aspect 23, wherein the means for segmented anisotropic heat transfer comprises a thermally insulating material, wherein the plurality of first thermally anisotropic conductive channels is part of a first portion of the means for segmented anisotropic heat transfer, wherein the plurality of second thermally anisotropic conductive channels is part of a second portion of the means for segmented anisotropic heat transfer, and wherein the first portion is coupled to the second portion through the thermally insulating material.

Aspect 25: The device of aspect 21, wherein the means for segmented anisotropic heat transfer includes a plurality of thermally anisotropic conductive channels aligned in a first direction, wherein the plurality of thermally anisotropic conductive channels have a high thermal conductivity value along a length of the plurality of thermally anisotropic conductive channels, and wherein the plurality of thermally anisotropic conductive channels have a low thermal conductivity value in a direction that is parallel to a width of one or more thermally anisotropic conductive channels.

Aspect 26: The device of aspects 21 through 25, wherein the means for segmented anisotropic heat transfer is configured to reduce the junction temperatures of the first integrated device and the second integrated device, and wherein the means for segmented anisotropic heat transfer is further configured to reduce a surface temperature of the device.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a region that includes a component configured to generate heat; and
a thermally conductive layer coupled to the region, wherein the thermally conductive layer includes a plurality of segmented thermally anisotropic conductive channels.

2. The device of claim 1, wherein at least one segmented thermally anisotropic conductive channel from the plurality of segmented thermally anisotropic conductive channels is aligned in a first direction.

3. The device of claim 2, wherein each segmented thermally anisotropic conductive channel from the plurality of segmented thermally anisotropic conductive channels is configured to provide a high thermal conductivity in the first direction and a low thermal conductivity in a second direction.

4. The device of claim 2, wherein the thermally conductive layer includes at least one adhesive that bonds the plurality of segmented thermally anisotropic conductive channels.

5. The device of claim 4,
wherein the plurality of segmented thermally anisotropic conductive channels includes a first segmented thermally anisotropic conductive channel and a second segmented thermally anisotropic conductive channel, and
wherein the at least one adhesive is located between at least the first segmented thermally anisotropic conductive channel and the second segmented thermally anisotropic conductive channel.

6. The device of claim 1,
wherein a first plurality of segmented thermally anisotropic conductive channels from the plurality of segmented thermally anisotropic conductive channels are aligned in a first direction, and
wherein a second plurality of segmented thermally anisotropic conductive channels from the plurality of segmented thermally anisotropic conductive channels are aligned in a second direction.

7. The device of claim 6,
wherein each segmented thermally anisotropic conductive channel from the first plurality of segmented thermally anisotropic conductive is configured to provide a high first thermal conductivity value in the first direction, and
wherein each segmented thermally anisotropic conductive channel from the second plurality of segmented thermally anisotropic conductive channels is configured to provide a high second thermal conductivity value in the second direction.

8. The device of claim 7, wherein the second direction is perpendicular to the first direction.

9. The device of claim 7, wherein the second direction is diagonal to the first direction.

10. The device of claim 1, wherein a segmented thermally anisotropic conductive channel from the plurality of segmented thermally anisotropic conductive channels is configured to provide a high thermal conductivity along a length of the segmented thermally anisotropic conductive channel.

11. The device of claim 10, wherein the thermally anisotropic conductive channel includes a thermally anisotropic conductive material that is configured to provide the high thermal conductivity along a first direction.

12. The device of claim 11,
wherein the thermally anisotropic conductive material has a high thermal conductivity value in the first direction, and
wherein the thermally anisotropic conductive material has a low thermal conductivity value in at least a second direction.

13. The device of claim 12,
wherein the first direction is along the length of the thermally anisotropic conductive channel, and
wherein the second direction is along a width of the thermally anisotropic conductive channel.

14. The device of claim 12,
wherein the thermally anisotropic conductive material includes a thermal conductivity value in the first direction that is in a range of approximately 1000-1900 Watts per meter kelvin (W/(mk)), and
wherein the thermally anisotropic conductive material includes a thermal conductivity value in the second direction that is less than 30 Watts per meter kelvin (W/(mk)).

15. The device of claim 1, wherein the thermally conductive layer comprises:
a first portion comprising a first plurality of segmented thermally anisotropic conductive channels from the plurality of segmented thermally anisotropic conductive channels;
a second portion comprising a second plurality of segmented thermally anisotropic conductive channels from the plurality of segmented thermally anisotropic conductive channels; and
a thermally insulating material coupled to the first portion and the second portion.

16. The device of claim 15,
wherein the first plurality of segmented thermally anisotropic conductive channels are aligned in a first direction, and
wherein the second plurality of segmented thermally anisotropic conductive channels are aligned in a second direction.

17. The device of claim 15,
wherein the thermally insulating material includes aerogel, and/or
wherein the thermally conductive layer includes graphite.

18. The device of claim 1,
wherein the region includes a first integrated device,
wherein the component includes a second integrated device, and
wherein the thermally conductive layer is configured to thermally decouple the first integrated device from the second integrated device.

19. The device of claim 1, wherein the device is configured to provide Wireless Fidelity (WiFi) communication and/or cellular communication.

20. The device of claim 1, wherein the device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A device comprising:
a region comprising:
a first integrated device configured to generate heat; and
a second integrated device configured to generate heat; and
means for segmented anisotropic heat transfer coupled to the region.

22. The device of claim 21,
wherein the means for segmented anisotropic heat transfer includes a plurality of thermally anisotropic conductive channels aligned in a first direction, and
wherein each thermally anisotropic conductive channel from the plurality of thermally anisotropic conductive channels is configured to provide high heat transfer capabilities in the first direction and low heat transfer capabilities in a direction parallel to a width of the thermally anisotropic conductive channel.

23. The device of claim 21,
wherein the means for segmented anisotropic heat transfer comprises:
a plurality of first thermally anisotropic conductive channels aligned in a first direction, and
a plurality of second thermally anisotropic conductive channels aligned in a second direction,
wherein each first thermally anisotropic conductive channel from the plurality of first thermally anisotropic conductive channels is configured to provide high heat transfer capabilities along a length of the first thermally anisotropic conductive channel, and
wherein each second thermally anisotropic conductive channel from the plurality of second thermally anisotropic conductive channels is configured to provide high heat transfer capabilities along a length of the second thermally anisotropic conductive channel.

24. The device of claim 23,
wherein the means for segmented anisotropic heat transfer comprises a thermally insulating material,
wherein the plurality of first thermally anisotropic conductive channels is part of a first portion of the means for segmented anisotropic heat transfer,
wherein the plurality of second thermally anisotropic conductive channels is part of a second portion of the means for segmented anisotropic heat transfer, and
wherein the first portion is coupled to the second portion through the thermally insulating material.

25. The device of claim 21,
wherein the means for segmented anisotropic heat transfer includes a plurality of thermally anisotropic conductive channels aligned in a first direction,
wherein the plurality of thermally anisotropic conductive channels have a high thermal conductivity value along a length of the plurality of thermally anisotropic conductive channels, and
wherein the plurality of thermally anisotropic conductive channels have a low thermal conductivity value in a direction that is parallel to a width of one or more thermally anisotropic conductive channels.

26. The device of claim 21,
wherein the means for segmented anisotropic heat transfer is configured to reduce the junction temperatures of the first integrated device and the second integrated device, and
wherein the means for segmented anisotropic heat transfer is further configured to reduce a surface temperature of the device.
